(19) United States
(12) Patent Application Publication
(10) Pub. No.: US 2026/0064004 A1
(43) Pub. Date: Mar. 5, 2026

(54) SEMICONDUCTOR MANUFACTURING APPARATUS AND METHOD

(71) Applicant: Taiwan Semiconductor Manufacturing Company, Ltd., Hsinchu (TW)

(72) Inventors: Yu Kai Chen, Kaohsiung City (TW); Shang-Sheng Li, Hsinchu City (TW); I-Chin Sung, Tainan City (TW)

(21) Appl. No.: 18/983,000

(22) Filed: Dec. 16, 2024

Related U.S. Application Data
(60) Provisional application No. 63/690,166, filed on Sep. 3, 2024.

(51) Int. Cl. G03F 7/30

(52) U.S. Cl. CPC G03F 7/3021

(57) ABSTRACT

A wafer processing apparatus according to the present disclosure includes an inner cup including a first cup wall and a first bottom surface, a middle cup enclosing the inner cup, the middle cup including a second cup wall and a second bottom surface between the first cup wall and the second cup wall, an outer cup enclosing the middle cup, the outer cup including a third cup wall and a third bottom surface between the second cup wall and the third cup wall, and a divider configured to move between a first position where a top surface of the divider is coplanar with the second bottom surface and a second position where the top surface of the divider rises above the second bottom surface.

### CROSS-REFERENCE TO RELATED APPLICATIONS

The present application claims priority to U.S. Provisional Patent Application Ser. No. 63/690,166, filed Sep. 3, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Photolithography is a key aspect of IC manufacturing. During lithography, one or more developers or developer solutions may be coated on a wafer to develop lithographic images. Catch cup(s) may be installed to prevent developers or solvents from being slung off a wafer as it spins during the developing process. When different developer solutions are allowed to mix, crystals may be formed in the drain terminals to reduce drain efficiency and cause contamination to the environment.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a wafer processing apparatus wherein a wafer holder is at a first position.

FIG. 2 illustrates a top view of the wafer processing apparatus in FIG. 1.

FIG. 3 illustrates a cross-sectional view of the wafer processing apparatus wherein a wafer holder is at a second position.

FIG. 4 illustrates a top view of the wafer processing apparatus in FIG. 3.

FIG. 5 illustrates a cross-sectional view of a wafer processing apparatus wherein a divider wall is mechanically coupled to a rotatable shaft, in accordance with one or more aspects of the present disclosure.

FIG. 6 illustrates a method 1000 of using wafer processing apparatus to develop latent images on photoresist layers on wafers, according to various aspects of the present disclosure.

FIGS. 7-14 illustrate cross sectional views of the wafer processing apparatus in FIG. 1 at various stages of fabrication of method 1000 in accordance with some embodiments of the present disclosure.

FIG. 15 illustrates a cross-sectional view of a wafer processing apparatus wherein a wafer holder is at a first position.

FIG. 16 illustrates a side view of an upper middle cup and a lower middle cup of the wafer processing apparatus in FIG. 15 when a spring door in the lower middle cup is not activated.

FIG. 17 illustrates a side view of an upper middle cup and a lower middle cup of the wafer processing apparatus in FIG. 15 when a spring door in the lower middle cup is activated.

FIG. 18 illustrates a top view of an inner cup wall, a divider, and a lower middle cup of the wafer processing apparatus in FIG. 15.

FIG. 19 illustrates a cross-sectional view of a wafer processing apparatus wherein a wafer holder is at a second position.

FIG. 20 illustrates a cross-sectional view of a wafer processing apparatus wherein a divider wall is mechanically coupled to a rotatable shaft, in accordance with one or more aspects of the present disclosure.

FIGS. 21-28 illustrate cross sectional views of the wafer processing apparatus in FIG. 15 at various stages of fabrication of method 1000 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

In the manufacturing processes for integrated circuits, a photolithography process, for example, is frequently used for forming features of a semiconductor device on a semiconductor wafer. The photolithography process generally involves applying a layer of photoresist to the semiconductor wafer surface followed by exposure to an activating light source through or reflected from a mask defining device feature patterns. The exposure forms a latent image in the photoresist layer. In general, a photoresist layer may be a positive photoresist or a negative photoresist. For a positive photoresist, a portion that is exposed to the activating light source may become soluble in a positive-tone developer while the unexposed portion remain insoluble. For a negative photoresist, a portion that is exposed to the activating light source may become insoluble while the unexposed portion remain soluble in a negative-tone developer. The semiconductor wafer is then subject to a development process to develop the latent image. During the development process, a negative-tone developer and a positive-tone developer may be dispensed over the photoresist layer on the semiconductor wafer while the semiconductor wafer is spinning. The negative-tone developer or positive-tone developer is distributed evenly over the wafer surface due to centrifugal forces. An excess portion of the developers may be slung off of the edge of the semiconductor wafer. The slung-off developers may be collected using a catch cup surrounding a wafer holder that secures the semiconductor wafer.

Modern-day lithography tools, such as coater or developer, are required to have multiple development chambers for different development processes. When a single development chamber can only be used with a positive-tone developer or a negative-tone developer, more development chambers would be needed to improve capacity and throughput of the tool. One of the solutions that have been put forth is a multi-developer development chamber that can handle both the positive-tone development and the negative-tone development. Because different developers are in different solvent systems, different developers may coagulate or form solids when they are allowed to mix. Coagulation and solids may block the drains and solid waste may require incineration, which consumes energy and may lead to pollution.

The present disclosure describes a semiconductor processing apparatus that includes an inner cup surrounding a rotatable shaft, a middle cup surrounding the inner cup, and an outer cup surrounding the middle cup. The inner cup includes a first cup wall and a first bottom surface. The middle cup includes a second cup wall and a second bottom surface. The outer cup includes a third cup wall and a third bottom surface. The semiconductor process apparatus further includes a divider. The divider is configured to move between a first position where a top surface of the divider is coplanar with the second bottom surface and a second position where the top surface of the divider rises above the second bottom surface. The present disclosure also describes a method of using the semiconductor processing apparatus. When a first developer is used, a first semiconductor wafer is at the first position such that the waste first developer may be collected between the inner cup and the middle cup. When a second developer is used, a second semiconductor wafer is at the second position and the divider is raised to form an inner channel between the inner cup and the middle cup. When the second semiconductor wafer rotates at a lower speed, a portion of the waste second developer may be collected in the inner channel. When the second semiconductor wafer rotates at a higher speed, substantially all of the waste second developer may be collected between the outer cup and the middle cup.

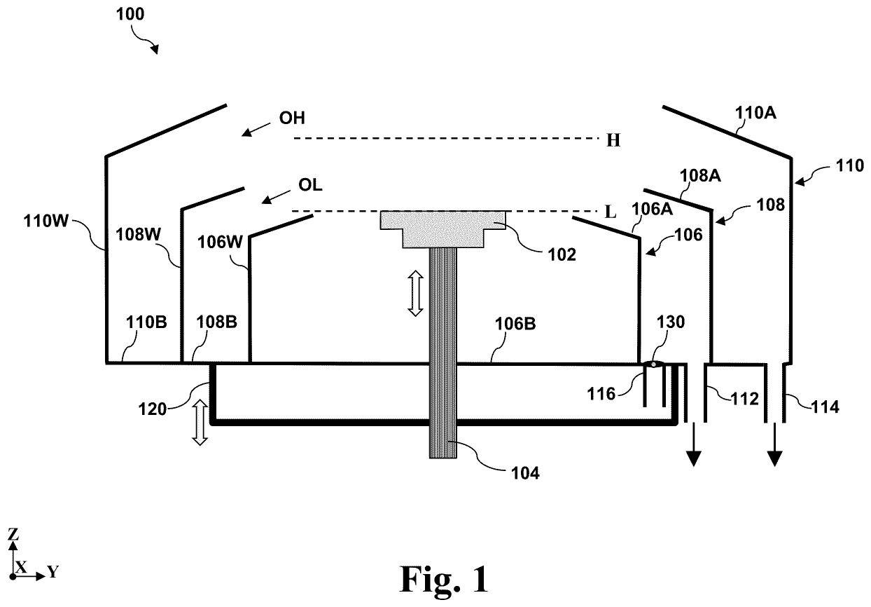

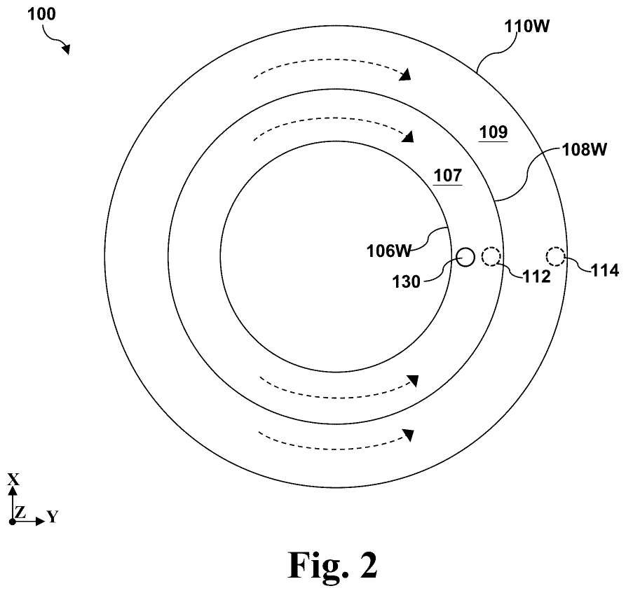

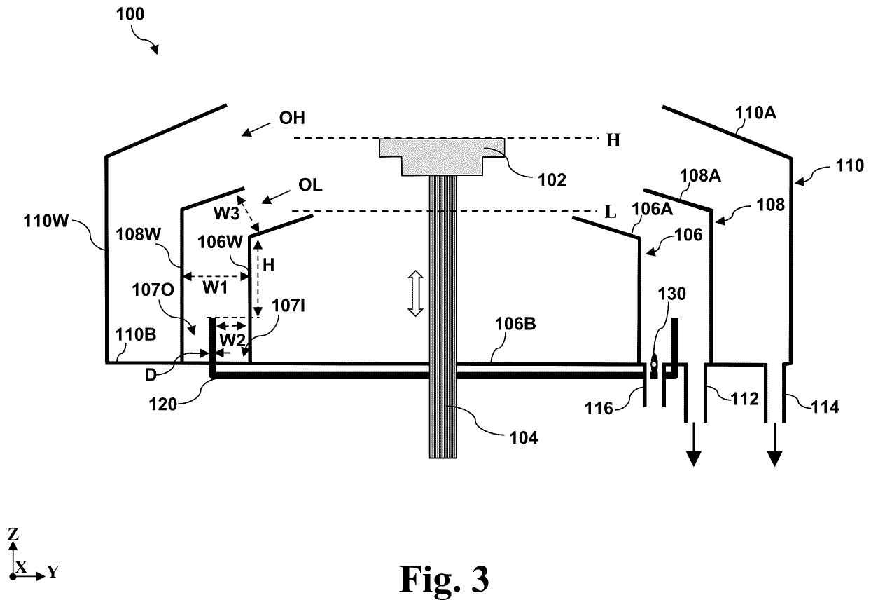

FIG. 1 illustrates a cross-sectional view of a wafer processing apparatus 100 according to some embodiments of the present disclosure. The wafer processing apparatus 100 includes a rotatable shaft 104 and a wafer chuck 102 that is mechanically secured to the rotatable shaft 104. The rotatable shaft 104 may be directly or indirectly driven by a direct-current (DC) motor to rotate at different speeds. When the rotatable shaft 104 rotates, the wafer chuck 102 also rotates with it. The wafer chuck 102 may be an electrostatic chuck (or E-chuck) and is configured to releasably secure a semiconductor wafer by electrostatic force. In some embodiments represented in FIG. 1, the wafer chuck 102 and the rotatable shaft 104 are surrounded by an inner cup 106. The inner cup 106 is surrounded by a middle cup 108, which is surrounded by an outer cup 110. The inner cup 106 includes a first bottom surface 106B, a first cup wall 106W extending from the first bottom surface 106B and a first angled top portion 106A extending from the first cup wall 106W. The middle cup 108 includes a second bottom surface 108B, a second cup wall 108W extending from the second bottom surface 108B and a second angled top portion 108A extending from the second cup wall 108W. As illustrated in FIGS. 1 and 3, each of the first angled top portion 106A, the second angled top portion 108A and the third angled top portion 110A bends inward toward the wafer chuck 102 or rotatable shaft 104. The outer cup 110 includes a third bottom surface 110B, a third cup wall 110W extending from the third bottom surface 110B, and a third angled top portion 110A extending from the third cup wall 110W. Reference is made to FIG. 2, which is a top view of the wafer processing apparatus 100 in FIG. 1. As shown in FIG. 2, the first cup wall 106W, the second cup wall 108W and the third cup wall 110W are circular and concentric. The second cup wall 108W extends continuously around the first cup wall 106W to define a first drain channel 107. The third cup wall 110W extends continuously around the second cup wall 108W to define a second drain channel 109.

In some embodiments represented in FIG. 1, the first bottom surface 106B, the second bottom surface 108B, and the third bottom surface 110B may be coplanar (i.e., extending along the same plane). As shown in FIG. 1, the second bottom surface 108B and the third bottom surface 110B include a first drain opening 112 and a second drain opening 114, respectively, to drain waste developers from the first drain channel 107 and the second drain channel 109. For illustration purposes, FIG. 2 includes arrows to indicate flow of liquid waste towards the drain openings. In some embodiments illustrated in FIGS. 1 and 2, the second bottom surface 108B further includes a third drain opening 116. Unlike the first drain opening 112 and the second drain opening 114, the third drain opening 116 is controlled by a valve 130. When the valve 130 is open, the third drain opening 116 is open and is available to drain liquid waste. When the valve 130 is shut, the third drain opening 116 is closed and is unavailable to drain any liquid waste. In some embodiments, the valve 130 may be a butterfly valve, a ball valve, a globe valve, or a check valve.

Reference is made to FIGS. 1 and 3. The rotatable shaft 104 and the wafer chuck 102 may vertically move between a lower position L and a higher position H. When the wafer chuck 102 is at the lower position L as shown in FIG. 1, a top surface of the wafer chuck 102 is higher than a top surface of the first angled top portion 106A but lower than a top surface of the second angled top portion 108A. When the wafer chuck 102 is at the higher position H as shown in FIG. 3, the top surface of the wafer chuck 102 is higher than the top surface of the second angled top portion 108A but lower than a top surface of the third angled top portion 110A. As illustrated in FIGS. 1 and 3, the first angled top portion 106A and the second angled top portion 108A define a lower catch opening OL. The second angled top portion 108A and the third angled top portion 110A define an upper catch opening OH.

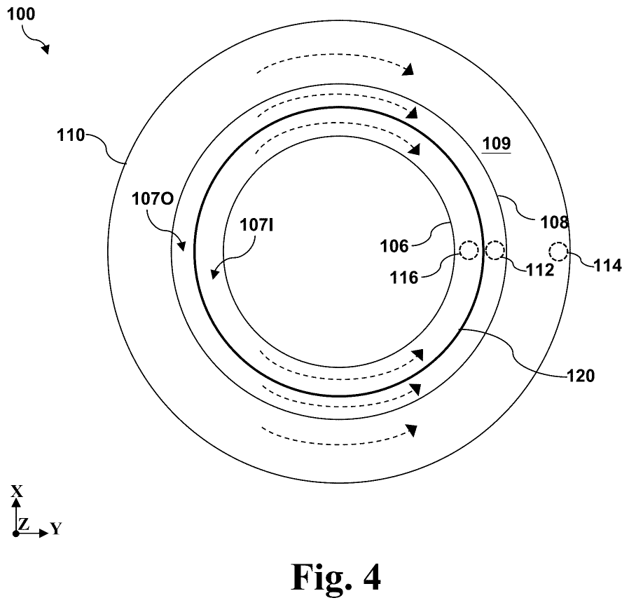

As shown in FIGS. 1 and 3, the wafer processing apparatus 100 includes a divider 120. The divider 120 is configured to vertically move between a lower position shown in FIG. 1 and an upper position shown in FIG. 3. When the divider 120 is at the lower position as shown in FIG. 1, a top surface of the divider 120 is level with the second bottom surface 108B to allow unrestricted flow of liquid in the first drain channel 107 toward the first drain opening 112. When the divider 120 is at the upper position as shown in FIG. 3, the top surfaces of the divider 120 rises above the second bottom surface 108B and divides the first drain channel 107 into an inner channel 1071 adjacent the first cup wall 106W and an outer channel 1070 adjacent the second cup wall 108W. In some embodiments represented in FIG. 3, when the divider 120 is at the upper position, the valve 130 is activated to open the third drain opening 116. That is, due to operation of the divider 120 and the valve 130, the inner channel 1071 drains via the third drain opening 116 while the outer channel 1070 drains via the first drain opening 112, as indicated by the arrows in FIG. 4.

Reference is made to FIG. 3. Along a radial direction, the concentric first cup wall 106W and the second cup wall 108W defines a first width W1 for the first drain channel 107. A second width W2 of the inner channel 1071 is defined radially between the divider 120 and the first cup wall 106W. The first angled top portion 106A and the second angled top portion 108A is spaced apart by a third width W3. A top surface of the divider 120 is lower than the top surface of the first cup wall 106W by a height H. In some embodiments, a ratio of the second with W2 to the first width W1 is between about 0.1 and about 0.9. A ratio of the thickness T of the divider 120 to the first width W1 is between about 0.05 and about 0.3. A ratio of the third width W3 to the first width W1 is between about 0.3 and about 0.6. A ratio of the height H to the first width W1 is between about 0.2 and about 2.

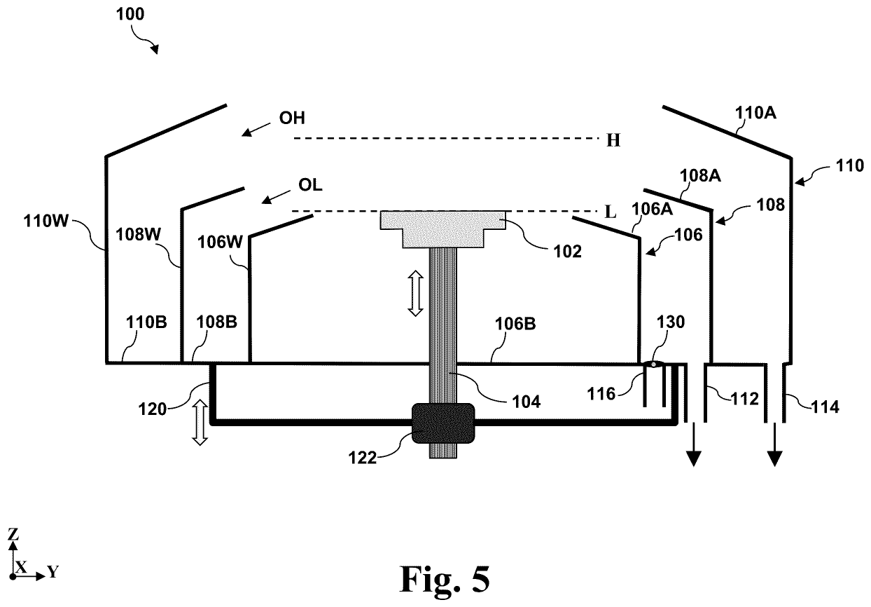

In some embodiments represented in FIG. 5, the divider 120 is mechanically coupled to a base member 122 that rises and lowers with the rotatable shaft 104. This base member 122 allows the divider 120 and the wafer chuck 102 rise and fall together. In these embodiments, when the wafer chuck 102 is at the lower portion L, the divider 120 is at the lower position with its top surface being level with the second bottom surface 108B. When the wafer chuck 102 is at the higher position H, the divider 120 is at the upper position with its top surface rising above the second bottom surface 108B to divide the first drain channel 107 into the inner channel 1071 and the outer channel 1070.

In some embodiments, the inner cup 106, the middle cup 108, the outer cup 110, the base member 122, and the divider 120 may include a chemical-resistant polymer, such as polypropylene (PP), polyvinyl chloride (PVC), high-density polyethylene (HDPE), polyetheretherketone (PEEK), polytetrafluoroethylene (PTFE), polyvinyldene fluoride, or polyaniline. The rotatable shaft 104 may be made of stainless steel.

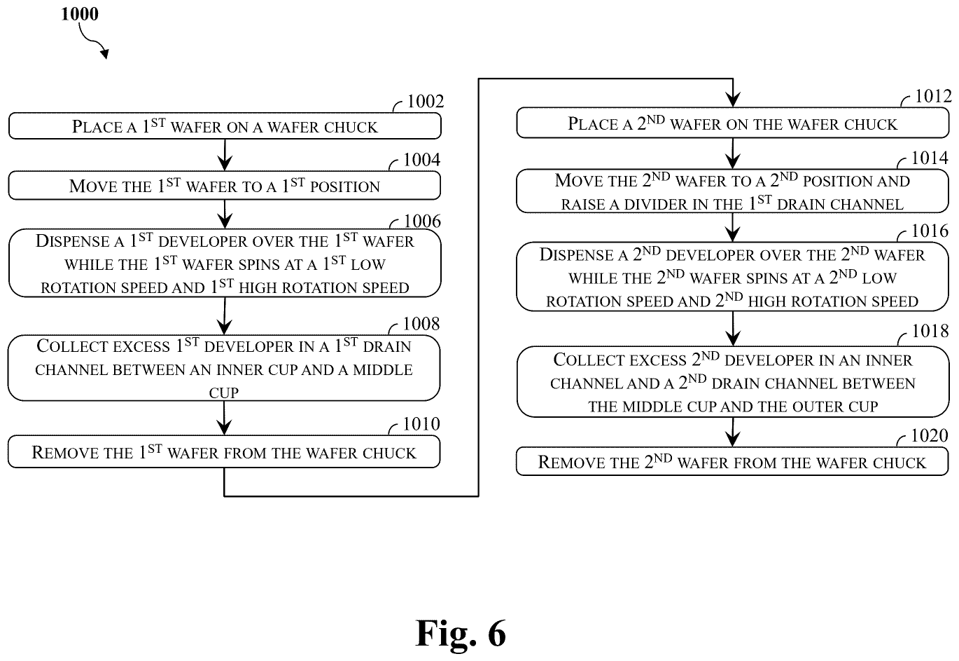

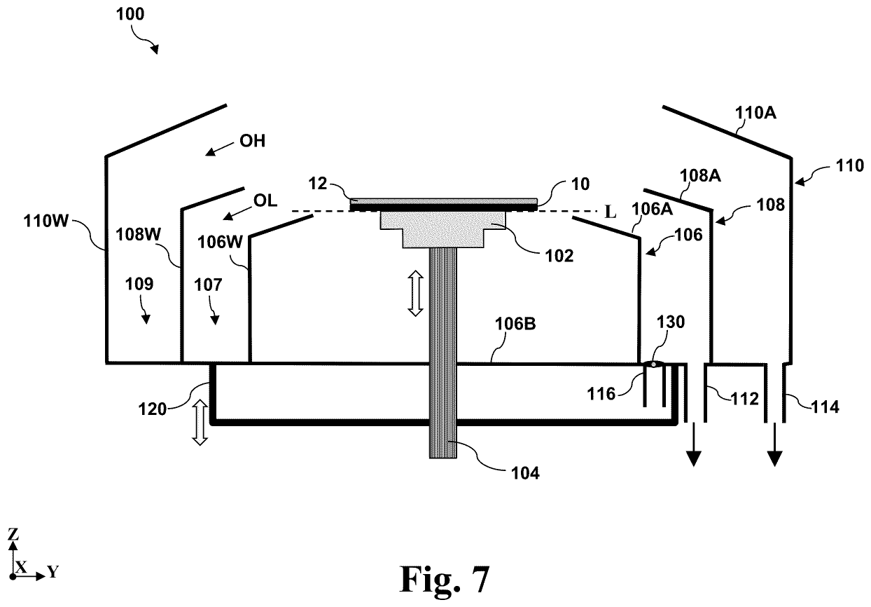

FIG. 6 illustrates a method 1000 of using the wafer processing apparatus 100 to develop latent images on photoresist layers on semiconductor wafers. Method 1000 is merely an example and is not intended to limit the present disclosure to what is explicitly illustrated in method 1000. Additional steps can be provided before, during and after method 1000, and some steps described can be replaced, eliminated, or moved around for additional embodiments of the method. Not all steps are described herein in detail for reasons of simplicity. Method 1000 is described below in conjunction with FIG. 7-14, which are cross-sectional views and top views of the wafer processing apparatus 100 at different stages of fabrication according to various embodiments of method 1000. For avoidance of doubts, the X, Y and Z directions in FIGS. 7-14 are perpendicular to one another. Throughout the present disclosure, unless expressly otherwise described, like reference numerals denote like features.

Referring to FIGS. 6 and 7, method 1000 includes a block 1002 where a first wafer 10 is placed on the wafer chuck 102. As described above, the wafer chuck 102 may be an E-chuck. At block 1002, the first wafer 10 is loaded on the wafer chuck 102 and the wafer chuck 102 is activated to secure the first wafer 10 on the wafer chuck. In some embodiments, the first wafer 10 is a semiconductor substrate that includes silicon (Si) in a crystalline structure. In alternative embodiments, the first wafer 10 includes other elementary semiconductors such as germanium (Ge); a compound semiconductor such as silicon carbide (SiC), gallium arsenide (GaAs), indium arsenide (IAs), and indium phosphide (InP); an alloy semiconductor such as GaAsP, AlInAs, AlGaAs, InGaAs, GaInP, and/or GaInAsP; or combinations thereof. The first wafer 10 may include a silicon on insulator (SOI) substrate, be strained/stressed for performance enhancement, include epitaxial regions, include isolation regions, include doped regions, include one or more semiconductor devices or portions thereof, include conductive and/or non-conductive layers, and/or include other suitable features and layers. While not explicitly shown in the figures, the first wafer 10 may include various device elements. Examples of device elements that are formed in the first wafer 10 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), etc.), diodes, and/or other applicable elements. The first wafer 10 also include a target layer, which is to be patterned using photolithography and etching processes. The target layer may be a metal layer, a metal nitride layer, a metal oxide layer, a dielectric layer, a bottom antireflective coating (BARC) layer, or an epitaxial layer. As shown in FIG. 7, the target layer of the first wafer 10 is coated with a first photoresist layer 12 thereon. In some embodiments, the first photoresist layer 12 may include a single layer or a multilayer, such as a tri-layer. The first photoresist layer 12 may include photoresist materials suitable for deep ultraviolet (DUV) lithography, extreme ultraviolet (EUV) lithography, electron beam (e-beam) lithography, x-ray lithography, and other appropriate lithography processes.

Before the first wafer 10 is loaded on the wafer chuck 102, the first photoresist layer 12 is exposed to radiation in a lithography system. In some embodiments, the radiation may be an I-line (365 nm), a DUV radiation such as KrF excimer laser (248 nm) or ArF excimer laser (193 nm), a EUV radiation (e.g., 13.8 nm), an e-beam, an x-ray, an ion beam, or other suitable radiations. The exposure may be performed in air, in a liquid (immersion lithography), or in a vacuum (e.g., for EUV lithography and e-beam lithography). The radiation is patterned with a photomask or reticle (not shown), such as a transmissive mask or a reflective mask, which may include resolution enhancement techniques such as phase-shifting and/or optical proximity correction (OPC). In the depicted embodiments, the first photoresist layer 12 is a positive photoresist. The portion of the first photoresist layer 12 that is exposed to radiation may depolymerize and becomes soluble in a positive tone developer. The exposure of the first photoresist layer 12 forms a latent image in the first photoresist layer 12. After the exposure process, the first photoresist layer 12 is subject to a post-bake process. The post-bake process is performed to assist in the generating, dispersing, and reacting of the acid/base/free radical generated from the impingement of the energy upon the photoactive compounds in the first photoresist layer 12 during the exposure process. The post-bake process helps to create or enhance chemical reactions which generate chemical differences and different polarities between the irradiated portions and the unexposed portions within the first photoresist layer 12. These chemical differences result in differences in the solubility between the irradiated portions and the unexposed portions.

Referring to FIGS. 6 and 7, method 1000 includes a block 1004 where the first wafer 10 is moved to a first position. As described above, the wafer chuck 102 of the wafer processing apparatus 100 may vertically move between the lower position L and the higher position H. At block 1004, the first position corresponds to the lower position L. At the lower position L, a bottom surface of the first wafer 10 is higher than the top surface of the inner cup 106 but is lower than the top surface of the middle cup 108 such that the lower catch opening OL opens up to an edge of the first wafer 10. Depending on the initial position of the wafer chuck 102, the wafer chuck 102 may lower to the lower position L.

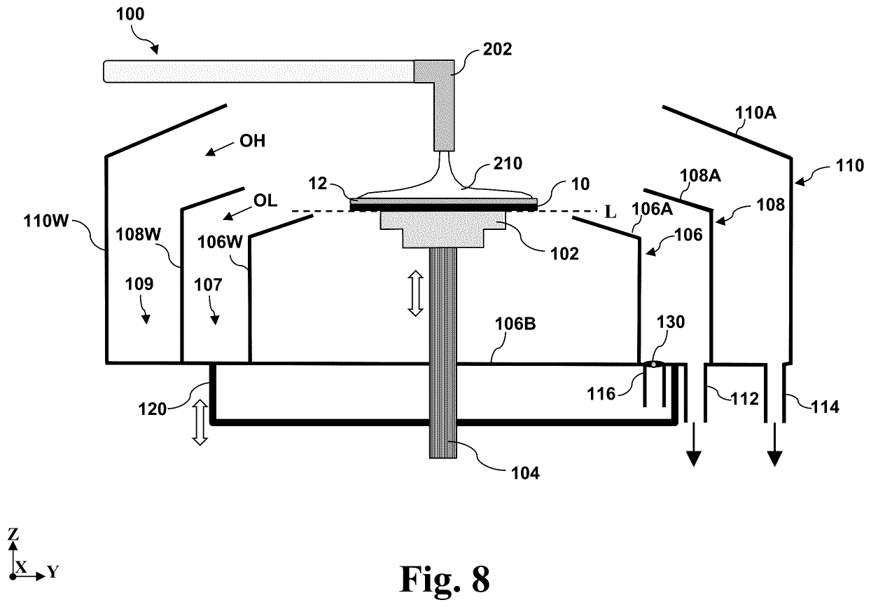

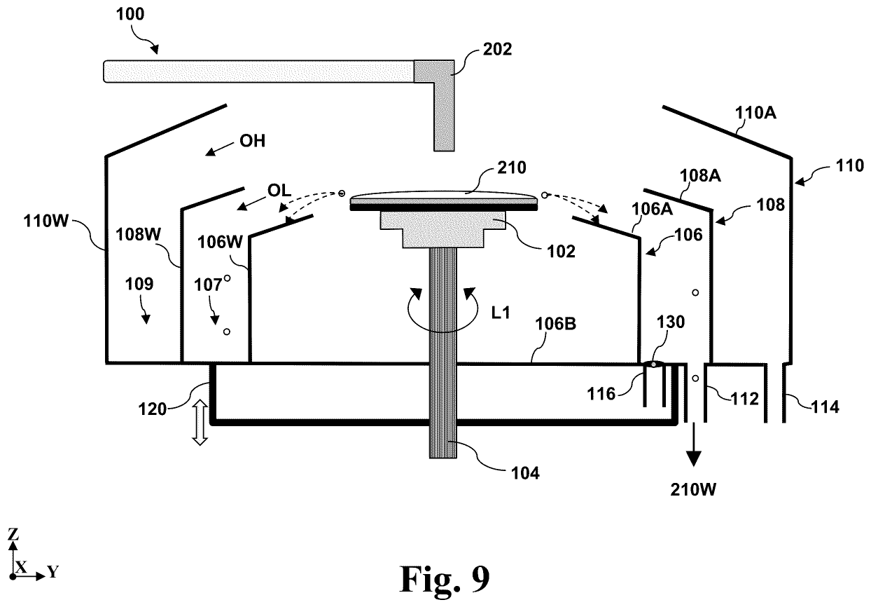

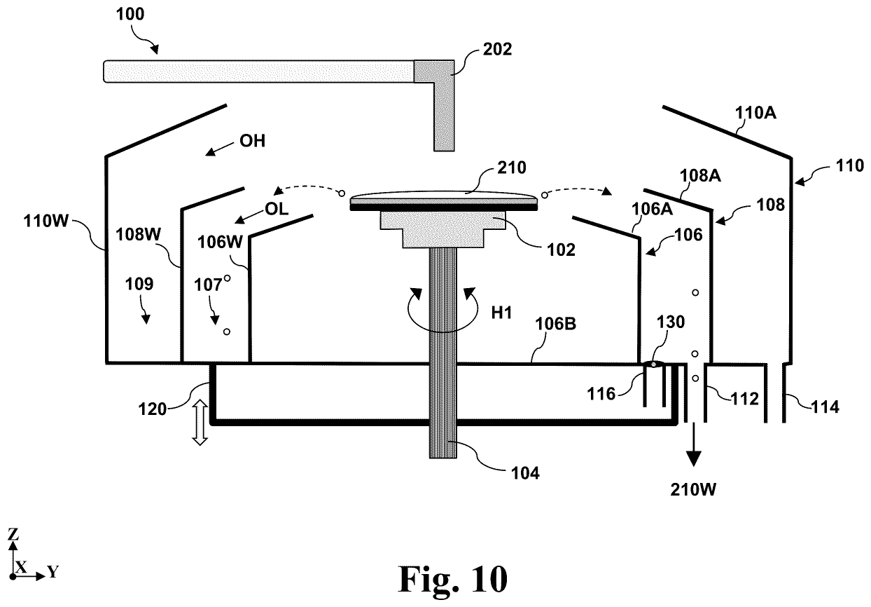

Referring to FIGS. 6 and 8-10, method 1000 includes a block 1006 where a first developer 210 is dispensed over the first wafer 10 while the first wafer 10 spins at a first low rotation speed L1 and a first high rotation speed H1. As illustrated in FIG. 8, at block 1006, a dispensing nozzle 202 lowers or rotates until it is at a suitable distance from a top surface of the first photoresist layer 12. At block 1006, the first developer 210 is dispensed from the dispensing nozzle 202 onto the first photoresist layer 12. As the first developer 210 is being dispensed over the first photoresist layer 12, the first wafer 10 spins along with the wafer chuck 102. In some embodiments represented in FIG. 8, the first wafer 10 (along with the wafer chuck 102) may rotate at a first low rotation speed L1 when the first developer 210 is first dispensed on the first wafer 10. In some embodiments, the first developer 210 is a positive-tone developer and may be an aqueous solution that includes tetramethylammonium hydroxide (TMAH), tetrabutylammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monocthylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminocthanol, ammonia, caustic soda, caustic potash, sodium metasilicate, potassium metasilicate, sodium carbonate, tetraethylammonium hydroxide, or a combination thereof. Thereafter, the first wafer 10 (along with the wafer chuck 102) may rotate at a greater first high rotation speed H1. In some instances, the first low rotation speed L1 is equal to or smaller than 200 revolutions per minute (RPM) while the first high rotation speed H1 is greater than 200 RPM. As shown in FIG. 9, when the wafer chuck 102 spins at the first low rotation speed L1, excess first developer 210 may be slung off an edge of the first wafer 10 and enter the first drain channel 107. As shown in FIG. 10, when the wafer chuck 102 spins at the first high rotation speed H1, excess first developer 210 may be slung off an edge of the first wafer 10 at a steeper angle. That said, as shown in FIG. 10, even at the first high rotation speed H1, excess first developer 210 may be collected in the first drain channel 107.

Referring to FIGS. 6, 9 and 10, method 1000 includes a block 1008 where the excess first developer 210 is collected in the first drain channel 107 between the inner cup 106 and the middle cup 108. As shown in FIGS. 9 and 10, excess first developer 210 may be slung off the edge of the first wafer 10 and collected in the first drain channel 107 between the inner cup 106 and the middle cup 108. To be more precise, the first drain channel 107 is defined between the first cup wall 106W and the second cup wall 108W. As illustrated in FIGS. 9 and 10, the excess first developer 210 may flow downhill toward the first drain opening 112. Please note that the third drain opening 116 remains closed off by the valve 130. The excess first developer 210 is directed to a first developer waste reservoir 210W.

Referring to FIG. 6, method 1000 includes a block 1010 where the first wafer 10 is removed from the wafer chuck 102. After the latent image in the first photoresist layer 12 is developed by the first developer 210, the first wafer 10 may be rinsed with deionized (DI) water to remove excess chemicals and then removed from the wafer chuck 102. In some embodiments, the first wafer 10 may be subject to a post-bake process to remove excess solvents.

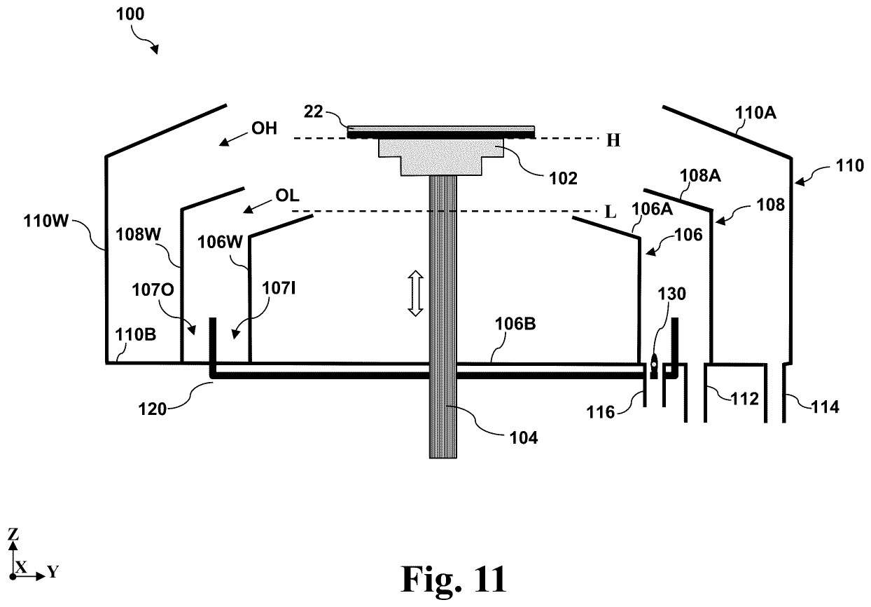

Referring to FIGS. 6 and 11, method 1000 includes a block 1012 wherein a second wafer 20 is placed on the wafer chuck 102. At block 1012, the second wafer 20 is loaded on the wafer chuck 102 and the wafer chuck 102 is activated to secure the second wafer 20 on the wafer chuck 102. Like the first wafer 10, the second wafer 20 is also a semiconductor substrate that includes silicon (Si). In alternative embodiments, the second wafer 20 includes other elementary semiconductors such as germanium (Ge); a compound semiconductor such as silicon carbide (SiC), gallium arsenide (GaAs), indium arsenide (IAs), and indium phosphide (InP); an alloy semiconductor such as GaAsP, AlInAs, AlGaAs, InGaAs, GaInP, and/or GaInAsP; or combinations thereof. The second wafer 20 may include a silicon on insulator (SOI) substrate, be strained/stressed for performance enhancement, include epitaxial regions, include isolation regions, include doped regions, include one or more semiconductor devices or portions thereof, include conductive and/or non-conductive layers, and/or include other suitable features and layers. While not explicitly shown in the figures, the second wafer 20 may include various device elements. Examples of device elements that are formed in the second wafer 20 include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field-effect transistors (PFETs/NFETs), etc.), diodes, and/or other applicable elements. The second wafer 20 also include a target layer, which may be a metal layer, a metal nitride layer, a metal oxide layer, a dielectric layer, a bottom antireflective coating (BARC) layer, or an epitaxial layer. As shown in FIG. 11, the second wafer 20 is coated with a second photoresist layer 22 thereon. The second photoresist layer 22 is deposited on the target layer, which is to be etched after the second photoresist layer 22 is patterned. In some embodiments, the second photoresist layer 22 may include a single layer or a multilayer, such as a tri-layer. The second photoresist layer 22 may include photoresist materials suitable for deep ultraviolet (DUV) lithography, extreme ultraviolet (EUV) lithography, electron beam (e-beam) lithography, x-ray lithography, and other appropriate lithography processes.

Before the second wafer 20 is loaded on the wafer chuck 102, the second photoresist layer 22 is exposed to radiation in a lithography system. In some embodiments, the radiation may be an I-line (365 nm), a DUV radiation such as KrF excimer laser (248 nm) or ArF excimer laser (193 nm), a EUV radiation (e.g., 13.8 nm), an e-beam, an x-ray, an ion beam, or other suitable radiations. The exposure may be performed in air, in a liquid (immersion lithography), or in a vacuum (e.g., for EUV lithography and e-beam lithography). The radiation is patterned with a photomask or reticle (not shown), such as a transmissive mask or a reflective mask, which may include resolution enhancement techniques such as phase-shifting and/or optical proximity correction (OPC). In the depicted embodiments, the second photoresist layer 22 is a negative resist. The portion of the second photoresist layer 22 that is exposed to radiation may become insoluble in a negative tone developer. The exposure of the second photoresist layer 22 forms a latent image in the second photoresist layer 22. After the exposure process, the second photoresist layer 22 is subject to a post-bake process. The post-bake process is performed to assist in the generating, dispersing, and reacting of the acid/base/free radical generated from the impingement of the energy upon the photoactive compounds in the second photoresist layer 22 during the exposure process. The post-bake process helps to create or enhance chemical reactions which generate chemical differences and different polarities between the irradiated portions and the unexposed portions within the second photoresist layer 22. These chemical differences result in differences in the solubility between the irradiated portions and the unexposed portions.

Referring to FIGS. 6 and 11, method 1000 includes a block 1014 where the second wafer 20 is moved to a second position and the divider 120 is raised in the first drain channel 107 to divide the first drain channel 107 into an inner channel 1071 and an outer channel 1070. As described above, the wafer chuck 102 of the wafer processing apparatus 100 may move vertically between the lower position L and the higher position H. At block 1014, the second position corresponds to the higher position H. At the higher position H, a bottom surface of the second wafer 20 is higher than the top surface of the middle cup 108 but is lower than the top surface of the outer cup 110 such that the higher catch opening OH opens up to an edge of the second wafer 20. Depending on the initial position of the wafer chuck 102, the wafer chuck 102 may raise to the higher position H. At block 1014, the divider 120 is raised such that its top surface rises above the second bottom surface 108B to divide the first drain channel 107 into the inner channel 1071 and the outer channel 1070. The inner channel 1071 is closer to the first cup wall 106W while the outer channel 1070 is closer to the second cup wall 108W. Additionally, at block 1014, the valve 130 that controls the third drain opening 116 is opened. When the divider 120 is raised and the valve 130 is open, the inner channel 1071 drains through the third drain opening 116 while the outer channel 1070 drains through the first drain opening 112.

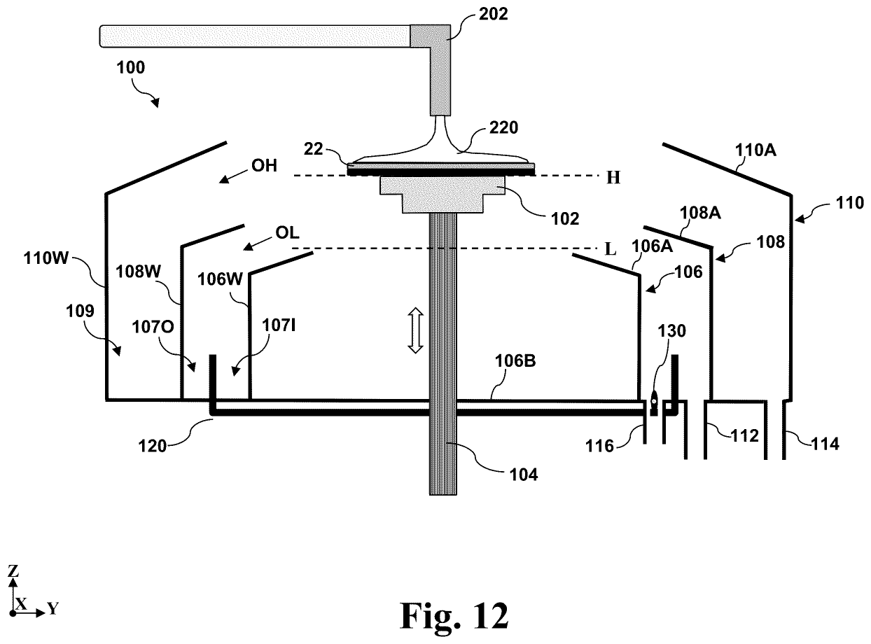

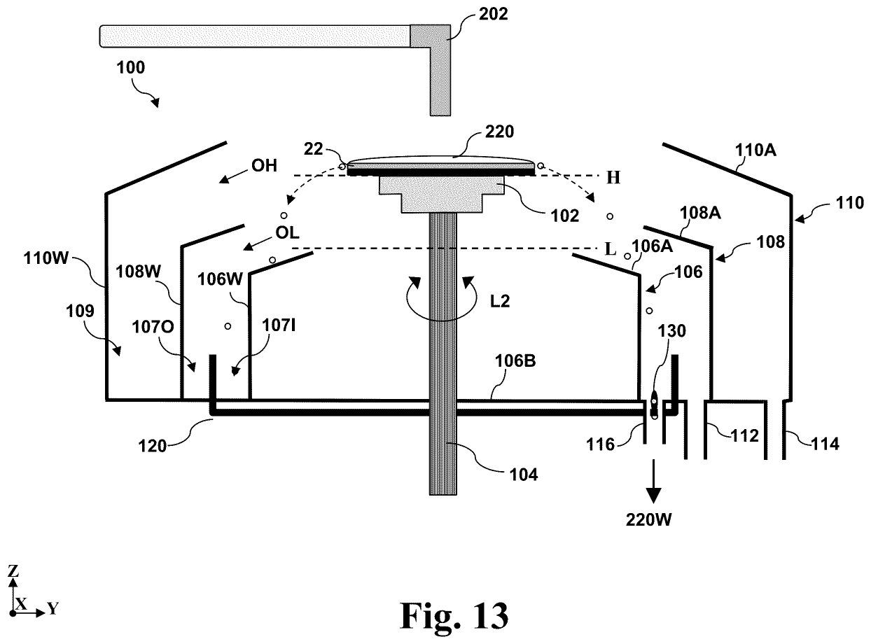

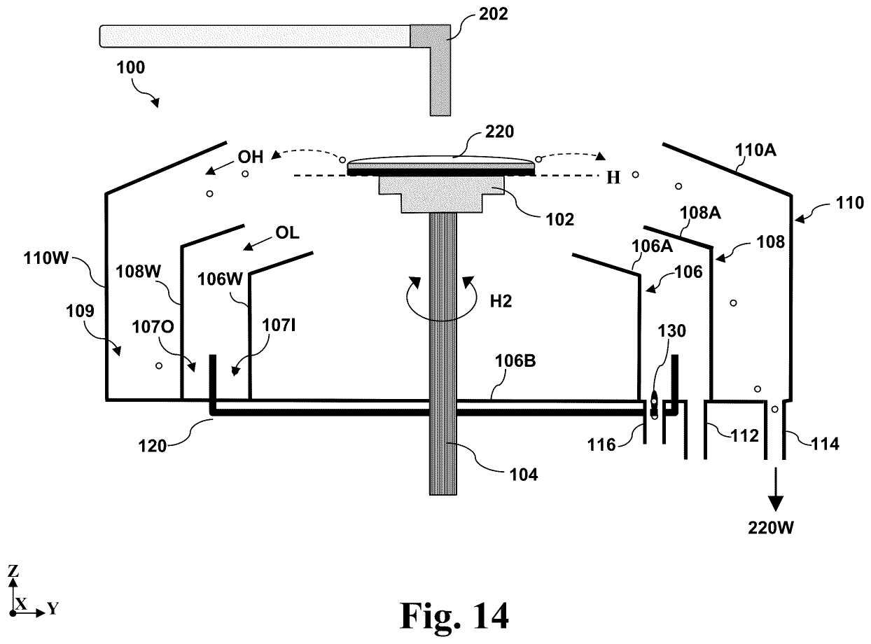

Referring to FIGS. 6, 12, 13, and 14, method 1000 includes a block 1016 where a second developer 220 is dispensed over the second wafer 20 while the second wafer 20 spins at a second low rotation speed L2 and a second high rotation speed H2. As illustrated in FIG. 12, at block 1016, the dispensing nozzle 202 lowers or rotates until it is at a suitable distance from a top surface of the second photoresist layer 22. At block 1016, the second developer 220 is dispensed from the dispensing nozzle 202 onto the second photoresist layer 22. In some embodiments, the second developer 220 is a negative-tone developer and may be an organic solution or solvent, such as hexane, heptane, octane, toluene, xylene, dichloromethane, chloroform, carbon tetrachloride, trichloroethylene, methanol, ethanol, propanol, butanol, diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether, acetone, methyl ethyl ketone, methyl isobutyl ketone, isophorone, cyclohexanone, methyl acetate, ethyl acetate, propyl acetate, butyl acetate, pyridine, formamide, N,N-dimethyl formamide, or a combination thereof. As the second developer 220 is being dispensed over the second photoresist layer 22, the second wafer 20 spins along with the wafer chuck 102. In some embodiments represented in FIG. 13, the second wafer 20 (along with the wafer chuck 102) may rotate at a second low rotation speed L2 when the second developer 220 is first dispensed on the second wafer 20. Thereafter, the second wafer 20 (along with the wafer chuck 102) may rotate at a greater second high rotation speed H2 as illustrated in FIG. 14. As shown in FIG. 13, when the wafer chuck 102 spins at the second low rotation speed L2, excess second developer 220 may be slung off an edge of the second wafer 20 and enter the inner channel 1071. It has been observed that when the wafer chuck 102 is at the higher position H and rotates at a speed smaller than 200 revolution per min (RPM), excess second developer 220 may not reach the upper catch opening OH. Instead, excess second developer 220 may fall on the first angled top portion 106A and enter the lower catch opening OL. This is where the divider 120 and the third drain opening 116 come in. Without the divider 120 and the third drain opening 116, excess second developer 220 may drain through the first drain opening 112 and enter the first developer waste reservoir 210W. Because the first developer 210 and the second developer 220 have different solvent types, mixing of the first developer 210 and the second developer 220 in the first developer waste reservoir 210W or the first drain channel 107 may result in coagulation or sedimentation. Such coagulation or sedimentation may reduce waste drainage efficiency and may increase energy and cost to treat mixed developer waste. As shown in FIG. 14, when the wafer chuck 102 spins at the second high rotation speed H2, excess second developer 220 may be slung off an edge of the second wafer 20 at a steeper angle. As shown in FIG. 14, at the second high rotation speed H2, excess second developer 220 may be collected in the second drain channel 109.

Referring to FIGS. 6, 13 and 14, method 1000 includes a block 1018 where the excess second developer 220 is collected in the inner channel 1071 and the second drain channel 109 between the middle cup 108 and the outer cup 110. As shown in FIGS. 13 and 14, excess second developer 220 may be slung off the edge of the second wafer 20 and collected in the inner channel 1071 and the second drain channel 109 between the middle cup 108 and the outer cup 110. The inner channel 1071 is defined between the first cup wall 106W and the divider 120. The second drain channel 109 is defined between the second cup wall 108W and the third cup wall 110W. As illustrated in FIGS. 13 and 14, the excess second developer 220 may flow downhill toward the second drain opening 114 and the third drain opening 116. Different from the first drain opening 112, the second drain opening 114 and the third drain opening 116 lead to a second developer waste reservoir 220W, which is separate from the first developer waste reservoir 210W.

Referring to FIG. 6, method 1000 includes a block 1020 where the second wafer 20 is removed from the wafer chuck 102. After the latent image in the second photoresist layer 22 is developed by the second developer 220, the second wafer 20 may be rinsed to remove excess chemicals and then removed from the wafer chuck 102. In some embodiments, the second wafer 20 may be subject to a post-bake process to remove excess solvents.

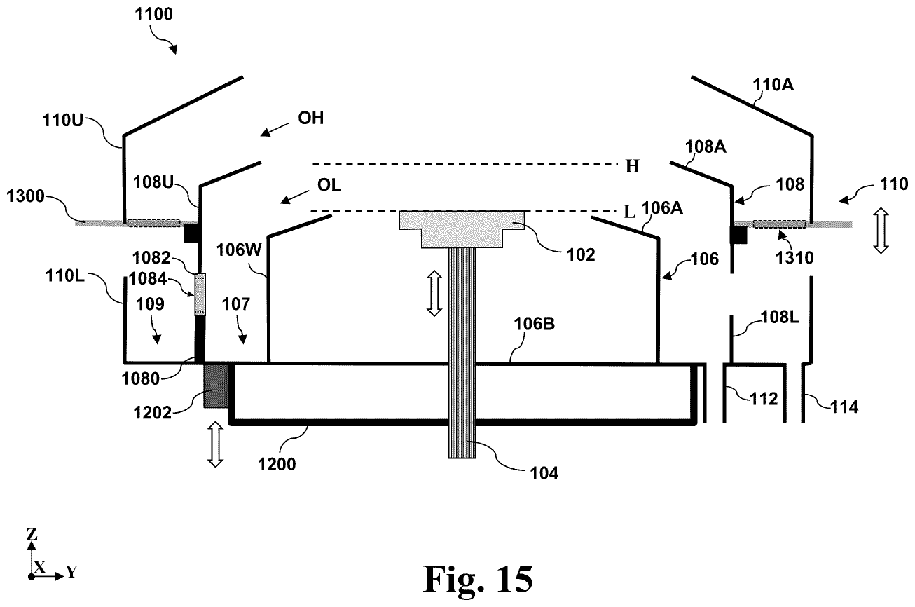

FIG. 15 illustrates a cross-sectional view of a wafer processing apparatus 1100. The wafer processing apparatus 1100 share some similar components with the wafer processing apparatus 100 described above. For purposes of describing the wafer processing apparatus 100 and the wafer processing apparatus 100, like reference numerals denote like features unless expressly described otherwise. Like the wafer processing apparatus 100 described above, the wafer processing apparatus 1100 includes a rotatable shaft 104 and a wafer chuck 102 that is mechanically secured to the rotatable shaft 104. The wafer chuck 102 and the rotatable shaft 104 are surrounded by an inner cup 106. The inner cup 106 is surrounded by a middle cup 108, which is surrounded by an outer cup 110. In some embodiments represented in FIG. 15, the middle cup 108 includes a lower middle cup 108L and an upper middle cup 108U and the outer cup 110 includes a lower outer cup 110L and an upper outer cup 110U. The inner cup 106 includes a first bottom surface 106B, a first cup wall 106W extending from the first bottom surface 106B and a first angled top portion 106A extending from the first cup wall 106W. The middle cup 108 includes a second angled top portion 108A, which is part of the upper middle cup 108U. The outer cup 110 a third angled top portion 110A, which is part of the upper outer cup 110U. As illustrated in FIG. 15, each of the first angled top portion 106A, the second angled top portion 108A and the third angled top portion 110A bends inward toward the wafer chuck 102 or rotatable shaft 104.

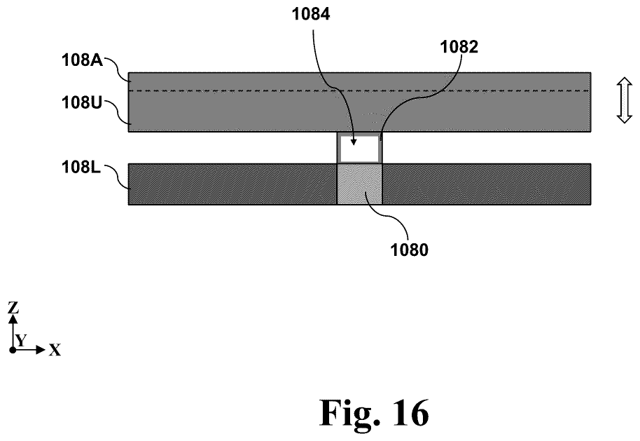

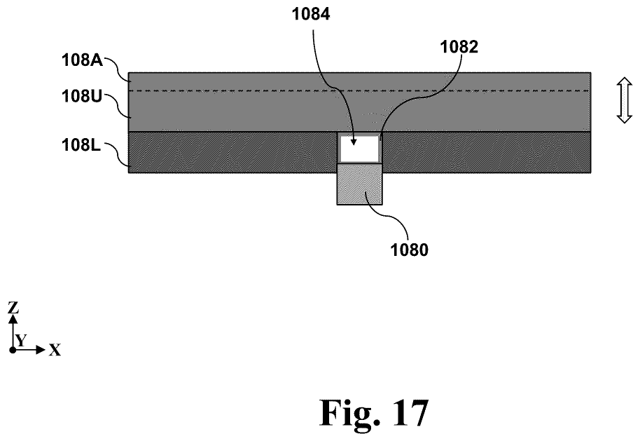

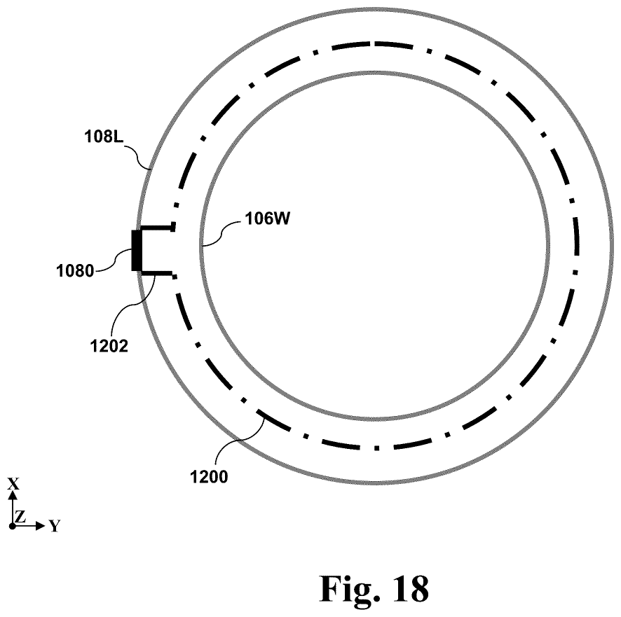

Reference is still made to FIG. 15. In the depicted embodiments, a bracket 1300 is mechanically attached to the upper middle cup 108U such that when the bracket 1300 is raised or lowered by a mechanical mechanism, the upper middle cup 108U also rises and falls with it. The upper outer cup 110U is disposed on a top surface of the bracket 1300 and also rises and falls with the bracket 1300. The bracket 1300 does not block the opening between the upper middle cup 108U and the upper outer cup 110U as it includes a bracket opening 1310. That is, both the upper outer cup 110U and the upper middle cup 108U are movable along the vertical direction (i.e., the Z direction) along with the bracket 1300. As shown in FIG. 15, the upper middle cup 108U and the lower middle cup 108L are not continuous. In fact, the upper middle cup 108U is vertically movable relative to the lower middle cup 108L. Similarly, the upper outer cup 110U is movable relative to the lower outer cup 110L. Reference is now made to FIGS. 15 and 16. The lower middle cup 108L includes a spring door 1080 that is spring-loaded and is movable vertically between an upper close position and a lower open position. The upper middle cup 108U includes a passage extension 1082 that extends lower than the rest of the upper middle cup 108U. FIGS. 16 and 17 illustrate a fragmentary sideview of the lower middle cup 108L, the spring door 1080, the passage extension 1082, and the upper middle cup 108U along the Y direction. Referring to FIG. 16, when the upper middle cup 108U is not lowered, the passage extension 1082 may contact or come close to a top surface of the spring door 1080. Referring to FIG. 17, when the upper middle cup 108U is lowered, the passage extension 1082 push on the top surface of the spring door 1080 to activate the spring door 1080. The passage extension 1082 includes a passage opening 1084. When the spring door 1080 is pushed down or activated by the passage extension 1082, the passage opening 1084 provides fluid communication across the lower middle cup 108L. As shown in FIGS. 16 and 17, the upper middle cup 108U also includes the second angled top portion 108A that bends toward the wafer chuck 102. The lower middle cup 108L extends continuously around the first cup wall 106W to define a first drain channel 107. The lower outer cup 110L extends continuously around the lower middle cup 108L to define a second drain channel 109. The first drain channel 107 drains through a first drain opening 112 and the second drain channel 109 drains through a second drain opening 114.

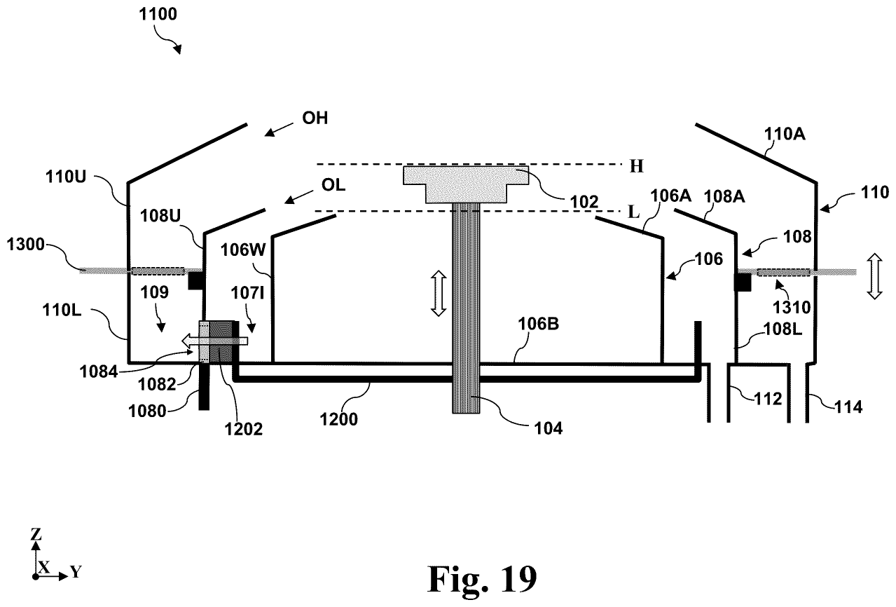

As shown in FIG. 15, the wafer processing apparatus 1100 includes a divider 1200 that includes a passage compartment 1202. The divider 1200 is configured to vertically move between a lower position shown in FIG. 15 and an upper position shown in FIG. 19. When the divider 1200 is at the lower position as shown in FIG. 15, a top surface of the divider 1200 does not extend into the first drain channel 107. When the divider 1200 is at the upper position as shown in FIG. 19, the top surface of the divider 1200, along with the passage compartment 1202, rises and extends into the first drain channel 107 to partition an inner channel 1071. Different from the wafer processing apparatus 100 described above, the inner channel 1071 does not have its own drain opening. When the divider 1200 is raised and the upper middle cup 108U is lowered, the passage extension 1082 attached to the upper middle cup 108U presses down the spring door 1080 such that the passage opening 1084 is aligned with the passage compartment 1202. As indicated by the arrow in FIG. 19, the alignment of the passage compartment 1202 and the passage opening 1084 provides fluid communication between the inner channel 1071 and the second drain channel 109. When liquid waste or fluid accumulates in the inner channel 1071, it may flow to the second drain channel 109 by way of the passage opening 1084 and the passage compartment 1202. The liquid waste or fluid in the second drain channel 109 may then drain by way of the second drain opening 114.

Reference is made to FIGS. 15 and 19. The rotatable shaft 104 and the wafer chuck 102 of the wafer processing apparatus 1100 may vertically move between a lower position L and a higher position H. When the wafer chuck 102 is at the lower position L as shown in FIG. 15, a top surface of the wafer chuck 102 is higher than a top surface of the first angled top portion 106A but lower than a top surface of the second angled top portion 108A. When the wafer chuck 102 is at the higher position H as shown in FIG. 19, the top surface of the wafer chuck 102 is higher than the top surface of the second angled top portion 108A but lower than a top surface of the third angled top portion 110A. As illustrated in FIGS. 15 and 19, the first angled top portion 106A and the second angled top portion 108A define a lower catch opening OL. The second angled top portion 108A and the third angled top portion 110A define an upper catch opening OH.

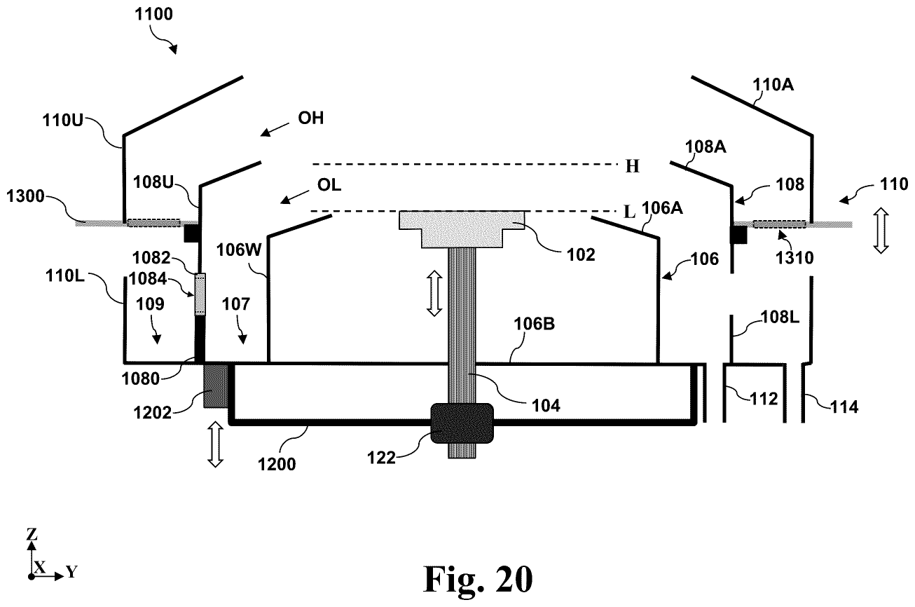

In some embodiments represented in FIG. 20, the divider 1200 is mechanically coupled to a base member 122 that rises and lowers with the rotatable shaft 104. This base member 122 allows the divider 1200 and the wafer chuck 102 rise and fall together. In these embodiments, when the wafer chuck 102 is at the lower portion L, the divider 1200 is at the lower position with its top surface not extending into the first drain channel 107. When the wafer chuck 102 is at the higher position H, the divider 1200 is at the upper position with its top surface extending into the first drain channel 107 to define the inner channel 1071.

In some embodiments, the inner cup 106, the middle cup 108, the outer cup 110, the base member 122, and the divider 1200 may include a chemical-resistant polymer, such as polypropylene (PP), polyvinyl chloride (PVC), high-density polyethylene (HDPE), polyetheretherketone (PEEK), polytetrafluoroethylene (PTFE), polyvinyldene fluoride, or polyaniline. The bracket 1300 and rotatable shaft 104 may be made of stainless steel.

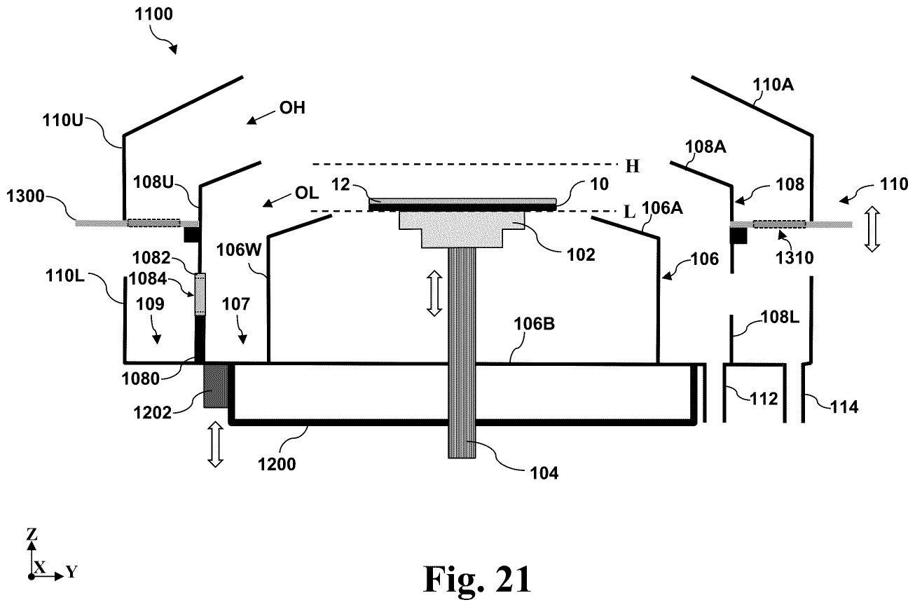

Method 1000 in FIG. 6 may be performed using the wafer processing apparatus 1100. Method 1000 is further described below in conjunction with FIG. 21-28, which are cross-sectional views the wafer processing apparatus 1100 at different stages of fabrication according to various embodiments of method 1000.

Referring to FIGS. 6 and 21, method 1000 includes a block 1002 where a first wafer 10 is placed on the wafer chuck 102. At block 1002, the first wafer 10 is loaded on the wafer chuck 102 and the wafer chuck 102 is activated to secure the first wafer 10 on the wafer chuck. The first wafer 10 also include a target layer, which is to be patterned using photolithography and etching processes. The target layer may be a metal layer, a metal nitride layer, a metal oxide layer, a dielectric layer, a bottom antireflective coating (BARC) layer, or an epitaxial layer. As shown in FIG. 21, the target layer of the first wafer 10 is coated with a first photoresist layer 12 thereon. In some embodiments, the first photoresist layer 12 may include a single layer or a multilayer, such as a tri-layer. The first photoresist layer 12 may include photoresist materials suitable for deep ultraviolet (DUV) lithography, extreme ultraviolet (EUV) lithography, electron beam (e-beam) lithography, x-ray lithography, and other appropriate lithography processes.

Before the first wafer 10 is loaded on the wafer chuck 102, the first photoresist layer 12 is exposed to radiation in a lithography system. The radiation is patterned with a photomask or reticle (not shown), such as a transmissive mask or a reflective mask, which may include resolution enhancement techniques such as phase-shifting and/or optical proximity correction (OPC). In the depicted embodiments, the first photoresist layer 12 is a positive photoresist. The portion of the first photoresist layer 12 that is exposed to radiation may depolymerize and becomes soluble in a positive tone developer. The exposure of the first photoresist layer 12 forms a latent image in the first photoresist layer 12. After the exposure process, the first photoresist layer 12 is subject to a post-bake process. The post-bake process is performed to assist in the generating, dispersing, and reacting of the acid/base/free radical generated from the impingement of the energy upon the photoactive compounds in the first photoresist layer 12 during the exposure process. The post-bake process helps to create or enhance chemical reactions which generate chemical differences and different polarities between the irradiated portions and the unexposed portions within the first photoresist layer 12. These chemical differences result in differences in the solubility between the irradiated portions and the unexposed portions.

Referring to FIGS. 6 and 21, method 1000 includes a block 1004 where the first wafer 10 is moved to a first position. At block 1004, the first position corresponds to the lower position L. At the lower position L, a bottom surface of the first wafer 10 is higher than the top surface of the inner cup 106 but is lower than the top surface of the middle cup 108 such that the lower catch opening OL opens up to an edge of the first wafer 10. Depending on the initial position of the wafer chuck 102, the wafer chuck 102 may lower to the lower position L.

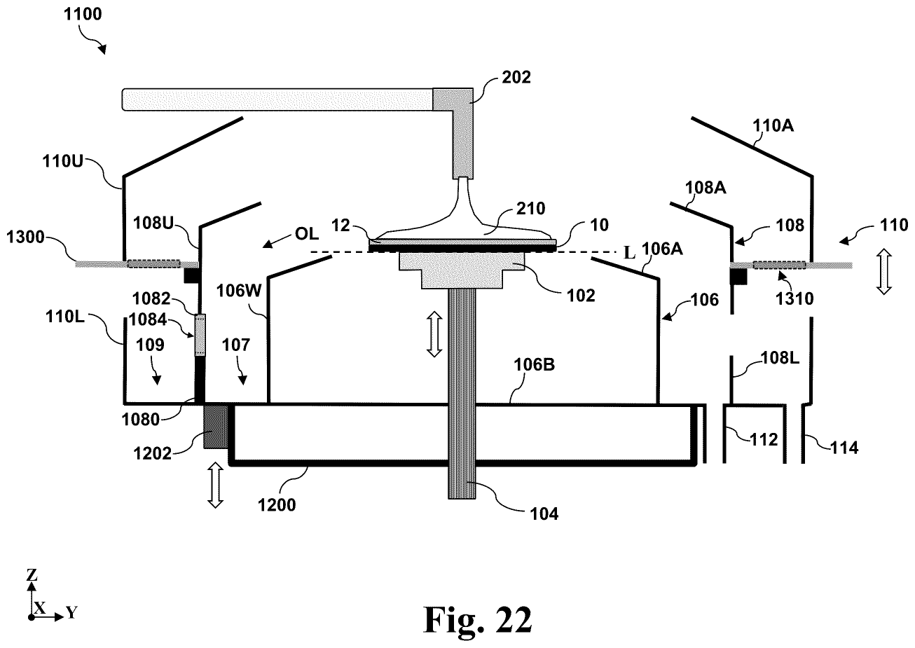

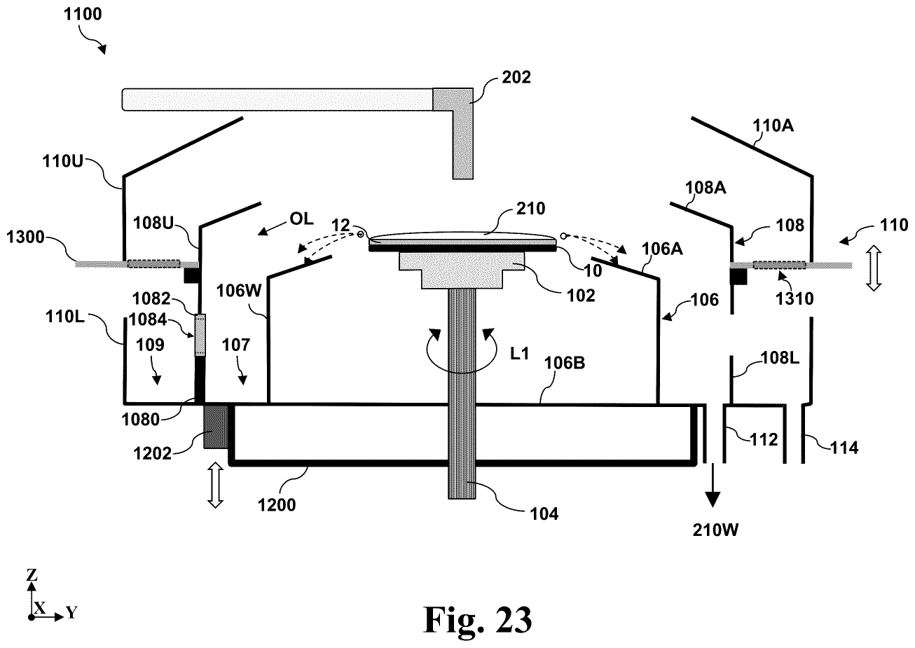

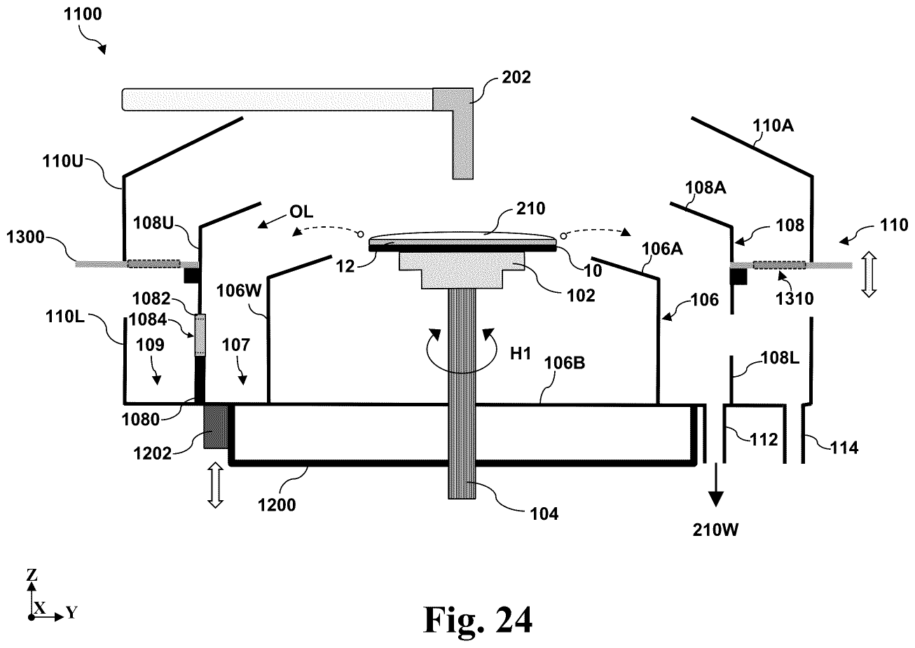

Referring to FIGS. 6 and 22-24, method 1000 includes a block 1006 where a first developer 210 is dispensed over the first wafer 10 while the first wafer 10 spins at a first low rotation speed L1 and a first high rotation speed H1. As illustrated in FIG. 22, at block 1006, a dispensing nozzle 202 lowers or rotates until it is at a suitable distance from a top surface of the first photoresist layer 12. At block 1006, the first developer 210 is dispensed from the dispensing nozzle 202 onto the first photoresist layer 12. As the first developer 210 is being dispensed over the first photoresist layer 12, the first wafer 10 spins along with the wafer chuck 102. In some embodiments represented in FIG. 23, the first wafer 10 (along with the wafer chuck 102) may rotate at a first low rotation speed L1 when the first developer 210 is dispensed on the first wafer 10. In some embodiments, the first developer 210 is a positive-tone developer and may be an aqueous solution that includes tetramethylammonium hydroxide (TMAH), tetrabutylammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monocthylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminoethanol, ammonia, caustic soda, caustic potash, sodium metasilicate, potassium metasilicate, sodium carbonate, tetraethylammonium hydroxide, or a combination thereof. Thereafter, the first wafer 10 (along with the wafer chuck 102) may rotate at a greater first high rotation speed H1. In some instances, the first low rotation speed L1 is equal to or smaller than 200 revolutions per minute (RPM) while the first high rotation speed H1 is greater than 200 RPM. As shown in FIG. 23, when the wafer chuck 102 spins at the first low rotation speed L1, excess first developer 210 may be slung off an edge of the first wafer 10 and enter the first drain channel 107. As shown in FIG. 24, when the wafer chuck 102 spins at the first high rotation speed H1, excess first developer 210 may be slung off an edge of the first wafer 10 at a steeper angle. That said, as shown in FIG. 24, even at the first high rotation speed H1, excess first developer 210 may be collected in the first drain channel 107.

Referring to FIGS. 6, 23 and 24, method 1000 includes a block 1008 where the excess first developer 210 is collected in the first drain channel 107 between the inner cup 106 and the middle cup 108. As shown in FIGS. 23 and 24, excess first developer 210 may be slung off the edge of the first wafer 10 and collected in the first drain channel 107 between the inner cup 106 and the middle cup 108. To be more precise, the first drain channel 107 is defined between the lower middle cup 108L and the lower outer cup 110L. As illustrated in FIGS. 23 and 24, the excess first developer 210 may be collected in the first drain channel 107 and drain through the first drain opening 112. The excess first developer 210 is directed to a first developer waste reservoir 210W.

Referring to FIG. 6, method 1000 includes a block 1010 where the first wafer 10 is removed from the wafer chuck 102. After the latent image in the first photoresist layer 12 is developed by the first developer 210, the first wafer 10 may be rinsed with deionized (DI) water to remove excess chemicals and then removed from the wafer chuck 102 of the wafer processing apparatus 1100. In some embodiments, the first wafer 10 may be subject to a post-bake process to remove excess solvents.

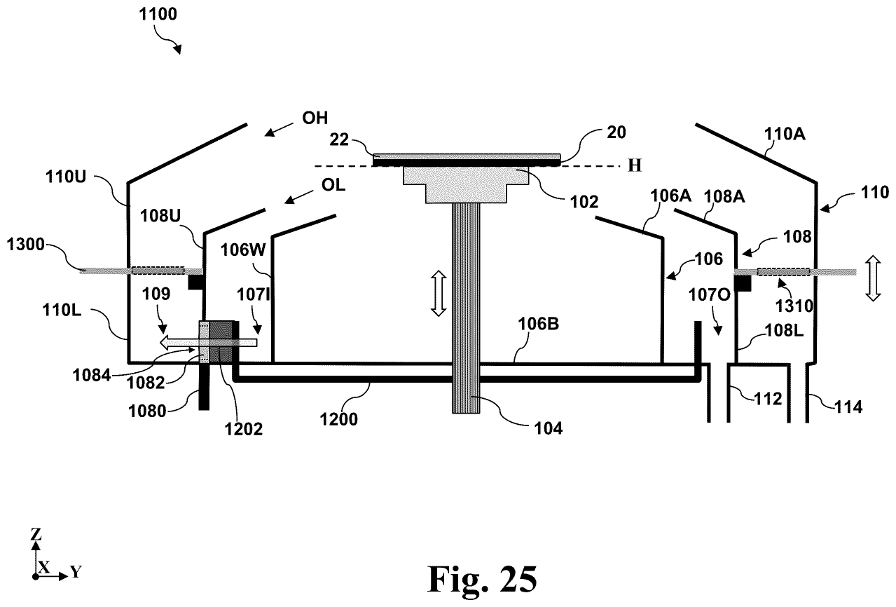

Referring to FIGS. 6 and 25, method 1000 includes a block 1012 wherein a second wafer 20 is placed on the wafer chuck 102. At block 1012, the second wafer 20 is loaded on the wafer chuck 102 and the wafer chuck 102 is activated to secure the second wafer 20 on the wafer chuck 102. The second wafer 20 also include a target layer, which may be a metal layer, a metal nitride layer, a metal oxide layer, a dielectric layer, a bottom antireflective coating (BARC) layer, or an epitaxial layer. As shown in FIG. 25, the second wafer 20 is coated with a second photoresist layer 22 thereon. The second photoresist layer 22 is deposited on the target layer, which is to be etched after the second photoresist layer 22 is patterned. In some embodiments, the second photoresist layer 22 may include a single layer or a multilayer, such as a tri-layer. The second photoresist layer 22 may include photoresist materials suitable for deep ultraviolet (DUV) lithography, extreme ultraviolet (EUV) lithography, electron beam (e-beam) lithography, x-ray lithography, and other appropriate lithography processes.

Before the second wafer 20 is loaded on the wafer chuck 102, the second photoresist layer 22 is exposed to radiation in a lithography system. The radiation is patterned with a photomask or reticle (not shown), such as a transmissive mask or a reflective mask, which may include resolution enhancement techniques such as phase-shifting and/or optical proximity correction (OPC). In the depicted embodiments, the second photoresist layer 22 is a negative resist. The portion of the second photoresist layer 22 that is exposed to radiation may become insoluble in a negative tone developer. The exposure of the second photoresist layer 22 forms a latent image in the second photoresist layer 22. After the exposure process, the second photoresist layer 22 is subject to a post-bake process. The post-bake process helps to create or enhance chemical reactions which generate chemical differences and different polarities between the irradiated portions and the unexposed portions within the second photoresist layer 22. These chemical differences result in differences in the solubility between the irradiated portions and the unexposed portions.

Referring to FIGS. 6 and 25, method 1000 includes a block 1014 where the second wafer 20 is moved to a second position and the divider 1200 is raised in the first drain channel 107 to define an inner channel 1071 and an outer channel 1070. As described above, the wafer chuck 102 of the wafer processing apparatus 1 100 may move vertically between the lower position L and the higher position H. At block 1014, the second position corresponds to the higher position H. At the higher position H, a bottom surface of the second wafer 20 is higher than the top surface of the middle cup 108 but is lower than the top surface of the outer cup 110 such that the higher catch opening OH opens up to an edge of the second wafer 20. Depending on the initial position of the wafer chuck 102, the wafer chuck 102 may raise to the higher position H. At block 1014, the divider 1200 is raised such that its top surface extends into the first drain channel 107 to divide the same into the inner channel 1071 and the outer channel 1070. The inner channel 1071 is closer to the first cup wall 106W while the outer channel 1070 is closer to the lower middle cup 108L. When the divider 1200 is raised and the upper middle cup 108U is lowered to activate the spring door 1080, the inner channel 1071 is in fluid communication to the second drain channel 109. The second drain channel 109 drains via the second drain opening 114.

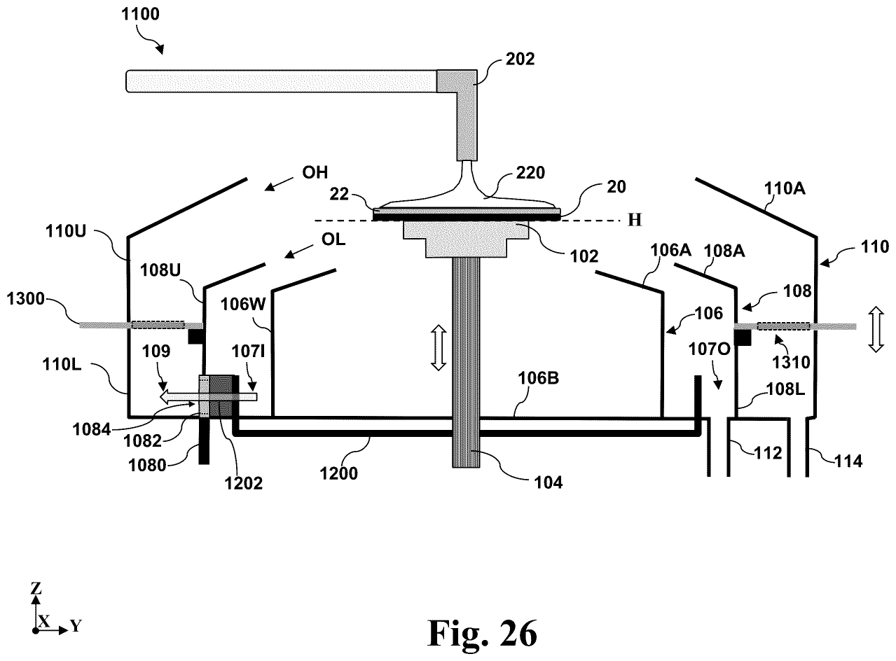

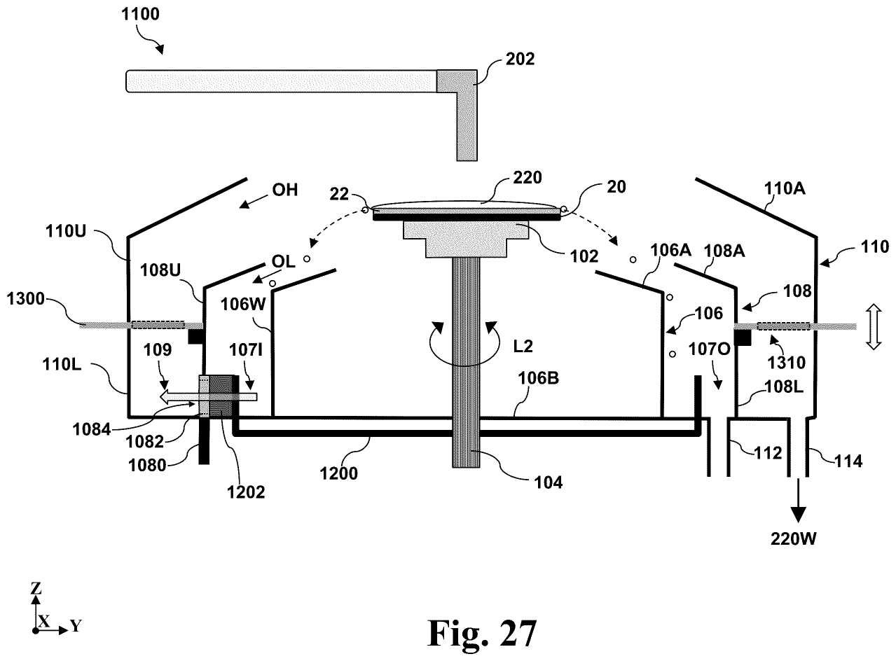

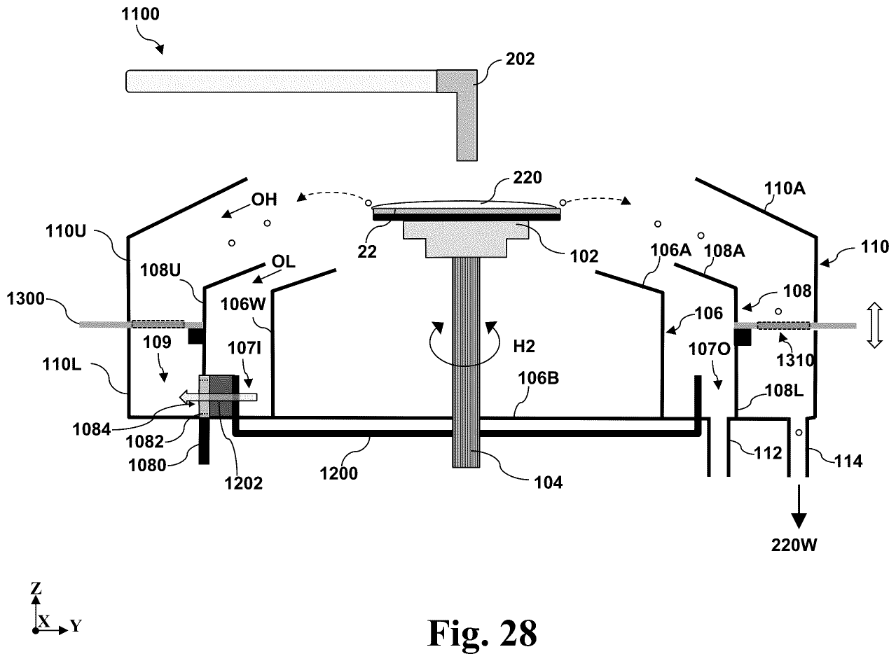

Referring to FIGS. 6, 26, 27, and 28, method 1000 includes a block 1016 where a second developer 220 is dispensed over the second wafer 20 while the second wafer 20 spins at a second low rotation speed L2 and a second high rotation speed H2. As illustrated in FIG. 26, at block 1016, the dispensing nozzle 202 lowers or rotates until it is at a suitable distance from a top surface of the second photoresist layer 22. At block 1016, the second developer 220 is dispensed from the dispensing nozzle 202 onto the second photoresist layer 22. In some embodiments, the second developer 220 is a negative-tone developer and may be an organic solution or solvent, such as hexane, heptane, octane, toluene, xylene, dichloromethane, chloroform, carbon tetrachloride, trichloroethylene, methanol, ethanol, propanol, butanol, diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether, acetone, methyl ethyl ketone, methyl isobutyl ketone, isophorone, cyclohexanone, methyl acetate, ethyl acetate, propyl acetate, butyl acetate, pyridine, formamide, N,N-dimethyl formamide, or a combination thereof. As the second developer 220 is being dispensed over the second photoresist layer 22, the second wafer 20 spins along with the wafer chuck 102. In some embodiments represented in FIG. 27, the second wafer 20 (along with the wafer chuck 102) may rotate at a second low rotation speed L2 when the second developer 220 is first dispensed on the second wafer 20. Thereafter, the second wafer 20 (along with the wafer chuck 102) may rotate at a greater second high rotation speed H2 as illustrated in FIG. 28. In some instances, the second low rotation speed L2 is equal to or smaller than 200 RPM while the second high rotation speed H2 is greater than 200 RPM. As shown in FIG. 27, when the wafer chuck 102 spins at the second low rotation speed L2, excess second developer 220 may be slung off an edge of the second wafer 20 and enter the inner channel 1071. It has been observed that when the wafer chuck 102 is at the higher position H and rotates at a speed smaller than 200 revolution per min (RPM), excess second developer 220 may not reach the upper catch opening OH. Instead, excess second developer 220 may fall on the first angled top portion 106A and enter the lower catch opening OL. This is where the divider 1200, the passage extension 1082, the spring door 1080, and the passage compartment 1202 operate to keep different developer fluids apart. Without the divider 1200, the passage extension 1082, the spring door 1080, and the passage compartment 1202, excess second developer 220 may drain through the first drain opening 112 and enter the first developer waste reservoir 210W. Because the first developer 210 and the second developer 220 have different solvent types (i.e., aqueous vs. organic), mixing of the first developer 210 and the second developer 220 in the first developer waste reservoir 210W or the first drain channel 107 may result in coagulation or sedimentation. Such coagulation or sedimentation may reduce waste drainage efficiency and may increase energy and cost to treat mixed developer waste. As shown in FIG. 28, when the wafer chuck 102 spins at the second high rotation speed H2, excess second developer 220 may be slung off an edge of the second wafer 20 at a steeper angle. As shown in FIG. 28, at the second high rotation speed H2, excess second developer 220 may be collected in the second drain channel 109.

Referring to FIGS. 6, 27 and 28, method 1000 includes a block 1018 where the excess second developer 220 is collected in the inner channel 1071 and the second drain channel 109 between the middle cup 108 and the outer cup 110. As shown in FIGS. 27 and 28, excess second developer 220 may be slung off the edge of the second wafer 20 and collected in the inner channel 1071 and the second drain channel 109. The inner channel 1071 is defined between the first cup wall 106W and the divider 1200. The second drain channel 109 is defined between the lower middle cup 108L and lower outer cup 110L. As illustrated in FIGS. 27 and 28, the excess second developer 220 may flow from the inner channel 1071 to the second drain channel 109 through the passage opening 1084. The excess second developer 220 in second drain channel 109 may then drain through the second drain opening 114, which leads to a second developer waste reservoir 220W, which is separate from the first developer waste reservoir 210W.

Referring to FIG. 6, method 1000 includes a block 1020 where the second wafer 20 is removed from the wafer chuck 102. After the latent image in the second photoresist layer 22 is developed by the second developer 220, the second wafer 20 may be rinsed to remove excess chemicals and then removed from the wafer chuck 102. In some embodiments, the second wafer 20 may be subject to a post-bake process to remove excess solvents.

In one example aspect, the present disclosure provides an apparatus. The apparatus includes an inner cup including a first cup wall and a first bottom surface, a middle cup enclosing the inner cup, the middle cup including a second cup wall and a second bottom surface between the first cup wall and the second cup wall, an outer cup enclosing the middle cup, the outer cup including a third cup wall and a third bottom surface between the second cup wall and the third cup wall, and a divider configured to move between a first position where a top surface of the divider is coplanar with the second bottom surface and a second position where the top surface of the divider rises above the second bottom surface.

In some embodiments, the divider is in the second position, the second bottom surface is divided by the divider into an inner bottom surface adjacent the first cup wall and an outer bottom surface away from the first cup wall. In some implementations, the apparatus may further include a first drain hole in the inner bottom surface, a second drain hole in the outer bottom surface, and a third drain hole in the third bottom surface. In some instances, the first drain hole and the third drain hole drain to a first waste container and the second drain hole drains to a second waste container different from the first waste container. In some embodiments, the apparatus further includes a rotatable shaft extending through the first bottom surface and a wafer holder mechanically coupled to the rotatable shaft. In some instances, the first cup wall completely surrounds the rotatable shaft, the second cup wall completely surrounds the first cup wall, and the third cup wall completely surrounds the second cup wall. In some embodiments, the first cup wall includes a first angled top portion that bends toward the rotatable shaft, the second cup wall includes a second angled top portion that bends toward the first angled top portion, and the third cup wall includes a third angled top portion that bends toward the second angled top portion. In some implementations, the first angled top portion and the second angled top portion define a lower catch opening, the second angled top portion and the third angled top portion define an upper catch opening, and the upper catch opening is disposed over the lower catch opening. In some embodiments, the wafer holder is movable between a high position and a low position. When the wafer holder is at the low position, the wafer holder is substantially level with the lower catch opening. When the wafer holder is at the high position, the wafer holder is substantially level with the upper catch opening.

Another aspect of the present disclosure pertains to an apparatus. The apparatus includes an inner cup including a first cup wall and a first bottom surface, a middle cup enclosing the inner cup, the middle cup including a second cup wall and a second bottom surface between the first cup wall and the second cup wall, an outer cup enclosing the middle cup, the outer cup including a third cup wall and a third bottom surface between the second cup wall and the third cup wall, a divider configured to move between a first position where a top surface of the divider is coplanar with the second bottom surface and a second position where the top surface of the divider rises above the second bottom surface, when the divider is in the second position, the second bottom surface is divided by the divider into an inner bottom surface adjacent the first cup wall and an outer bottom surface away from the first cup wall, a first drain hole in the inner bottom surface, a second drain hole in the outer bottom surface, and a third drain hole in the third bottom surface.

In some embodiments, the first drain hole and the third drain hole drain to a first waste container and the second drain hole drains to a second waste container different from the first waste container. In some implementations, the apparatus further includes a rotatable shaft extending through the first bottom surface, and a wafer holder mechanically coupled to the rotatable shaft. In some embodiments, the first cup wall completely surrounds the rotatable shaft, the second cup wall completely surrounds the first cup wall, and the third cup wall completely surrounds the second cup wall. In some embodiments, the first cup wall includes a first angled top portion that bends toward the rotatable shaft, the second cup wall includes a second angled top portion that bends toward the first angled top portion, and the third cup wall includes a third angled top portion that bends toward the second angled top portion. In some instances, the first angled top portion and the second angled top portion define a lower catch opening, the second angled top portion and the third angled top portion define an upper catch opening, and the upper catch opening is disposed over the lower catch opening.

Yet another aspect of the present disclosure pertains to a method. The method includes placing a first wafer on a wafer holder mechanically secured on a rotatable shaft surrounded by an inner cup that is surrounded by a middle cup that is surrounded by an outer cup, moving the first wafer to a first position higher than a first cup wall of the inner cup but lower than a second cup wall of the middle cup, dispensing a first developer over the first wafer, rotating the first wafer while collecting excess first developer in a first channel between the first cup wall and the second cup wall, removing the first wafer, placing a second wafer on the wafer holder, moving the second wafer to a second position higher than the second cup wall of the middle cup but lower than a third cup wall of the outer cup, causing a divider wall to raise in the first channel to divide the first channel into an inner channel closer to the first cup wall and an outer channel closer to the second cup wall, dispensing a second developer over the second wafer, rotating the second wafer while collecting excess second developer in a second channel between the second cup wall and the third cup wall and the inner channel, and removing the second wafer.

In some embodiments, the first developer is a positive tone developer and the second developer is a negative tone developer. In some implementations, the inner channel includes a first drain hole, outer channel includes a second drain hole, and the second channel includes a third drain hole. In some embodiments, before the causing of the divider wall to raise, the first drain hole is closed. In some embodiments, the causing of the divider wall to raise includes opening the first drain hole. In some embodiments, the moving of the second wafer to the second position and the causing of the divider wall to raise are performed at the same time.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
an inner cup comprising a first cup wall and a first bottom surface;
a middle cup enclosing the inner cup, the middle cup comprising a second cup wall and a second bottom surface between the first cup wall and the second cup wall;
an outer cup enclosing the middle cup, the outer cup comprising a third cup wall and a third bottom surface between the second cup wall and the third cup wall; and
a divider configured to move between a first position where a top surface of the divider is coplanar with the second bottom surface and a second position where the top surface of the divider rises above the second bottom surface.

2. The apparatus of claim 1, wherein when the divider is in the second position, the second bottom surface is divided by the divider into an inner bottom surface adjacent the first cup wall and an outer bottom surface away from the first cup wall.

3. The apparatus of claim 2, further comprising:
a first drain hole in the inner bottom surface;
a second drain hole in the outer bottom surface; and
a third drain hole in the third bottom surface.

4. The apparatus of claim 3,
wherein the first drain hole and the third drain hole drain to a first waste container,
wherein the second drain hole drains to a second waste container different from the first waste container.

5. The apparatus of claim 1, further comprising:
a rotatable shaft extending through the first bottom surface; and
a wafer holder mechanically coupled to the rotatable shaft.

6. The apparatus of claim 5,
wherein the first cup wall completely surrounds the rotatable shaft,
wherein the second cup wall completely surrounds the first cup wall,
wherein the third cup wall completely surrounds the second cup wall.

7. The apparatus of claim 6,
wherein the first cup wall comprises a first angled top portion that bends toward the rotatable shaft,
wherein the second cup wall comprises a second angled top portion that bends toward the first angled top portion,
wherein the third cup wall comprises a third angled top portion that bends toward the second angled top portion.

8. The apparatus of claim 7,
wherein the first angled top portion and the second angled top portion define a lower catch opening,
wherein the second angled top portion and the third angled top portion define an upper catch opening,
wherein the upper catch opening is disposed over the lower catch opening.

9. The apparatus of claim 8,
wherein the wafer holder is movable between a high position and a low position,
wherein when the wafer holder is at the low position, the wafer holder is substantially level with the lower catch opening,
wherein when the wafer holder is at the high position, the wafer holder is substantially level with the upper catch opening.

10. An apparatus, comprising:
an inner cup comprising a first cup wall and a first bottom surface;
a middle cup enclosing the inner cup, the middle cup comprising a second cup wall and a second bottom surface between the first cup wall and the second cup wall;
an outer cup enclosing the middle cup, the outer cup comprising a third cup wall and a third bottom surface between the second cup wall and the third cup wall;
a divider configured to move between a first position where a top surface of the divider is coplanar with the second bottom surface and a second position where the top surface of the divider rises above the second bottom surface, when the divider is in the second position, the second bottom surface is divided by the divider into an inner bottom surface adjacent the first cup wall and an outer bottom surface away from the first cup wall;
a first drain hole in the inner bottom surface;
a second drain hole in the outer bottom surface; and
a third drain hole in the third bottom surface.

11. The apparatus of claim 10,
wherein the first drain hole and the third drain hole drain to a first waste container,
wherein the second drain hole drains to a second waste container different from the first waste container.

12. The apparatus of claim 10, further comprising:
a rotatable shaft extending through the first bottom surface; and
a wafer holder mechanically coupled to the rotatable shaft.

13. The apparatus of claim 12,
wherein the first cup wall completely surrounds the rotatable shaft,
wherein the second cup wall completely surrounds the first cup wall,
wherein the third cup wall completely surrounds the second cup wall.

14. The apparatus of claim 13,
wherein the first cup wall comprises a first angled top portion that bends toward the rotatable shaft,
wherein the second cup wall comprises a second angled top portion that bends toward the first angled top portion,
wherein the third cup wall comprises a third angled top portion that bends toward the second angled top portion.

15. The apparatus of claim 14,
wherein the first angled top portion and the second angled top portion define a lower catch opening,
wherein the second angled top portion and the third angled top portion define an upper catch opening,
wherein the upper catch opening is disposed over the lower catch opening.

16. A method, comprising:
placing a first wafer on a wafer holder mechanically secured on a rotatable shaft surrounded by an inner cup that is surrounded by a middle cup that is surrounded by an outer cup;
moving the first wafer to a first position higher than a first cup wall of the inner cup but lower than a second cup wall of the middle cup;
dispensing a first developer over the first wafer;
rotating the first wafer while collecting excess first developer in a first channel between the first cup wall and the second cup wall;
removing the first wafer;
placing a second wafer on the wafer holder;
moving the second wafer to a second position higher than the second cup wall of the middle cup but lower than a third cup wall of the outer cup;
causing a divider wall to raise in the first channel to divide the first channel into an inner channel closer to the first cup wall and an outer channel closer to the second cup wall;
dispensing a second developer over the second wafer;
rotating the second wafer while collecting excess second developer in a second channel between the second cup wall and the third cup wall and the inner channel; and
removing the second wafer.

17. The method of claim 16,
wherein the first developer is a positive tone developer,
wherein the second developer is a negative tone developer.

18. The method of claim 16,
wherein the inner channel comprises a first drain hole,
wherein the outer channel comprises a second drain hole,
wherein the second channel comprises a third drain hole.

19. The method of claim 18,
wherein before the causing of the divider wall to raise, the first drain hole is closed,
wherein the causing of the divider wall to raise comprises opening the first drain hole.

20. The method of claim 16, wherein the moving of the second wafer to the second position and the causing of the divider wall to raise are performed at the same time.
